(19) United States
(12) Patent Application Publication
(10) Pub. No.: US 2013/0048062 A1
(43) Pub. Date: Feb. 28, 2013

(54) SOLAR CELL COMPRISING BULK HETEROJUNCTION INORGANIC THIN FILM AND FABRICATION OF THE SOLAR CELL

(71) Applicants: Byoung Koun MIN, Seoul (KR); Jaehoon KIM, Seoul (KR); Jin Woo CHO, Seoul (KR); Jeong Myeong HA, Seoul (KR); Chang Soo KIM, Daegu (KR)

(72) Inventors: Byoung Koun MIN, Seoul (KR); Jaehoon KIM, Seoul (KR); Jin Woo CHO, Seoul (KR); Jeong Myeong HA, Seoul (KR); Chang Soo KIM, Daegu (KR)

(73) Assignee: KOREA INSTITUTE OF SCIENCE AND TECHNOLOGY, Seoul (KR)

(21) Appl. No.: 13/332,627

(22) Filed: Dec. 21, 2011

(30) Foreign Application Priority Data
Aug. 29, 2011 (KR) 10-2011-0086514

(51) Int. Cl. H01L 31/0224; H01L 31/18; H01L 31/0352; B82Y 99/00

(52) U.S. Cl. 136/255; 136/256; 438/85; 977/948; 257/E31.126

(57) ABSTRACT

Provided is a bulk heterojunction inorganic thin film solar cell and a method for fabricating the same. More particularly, the solar cell includes an inorganic thin film having a bulk heterojunction formed by using vertically grown n-type semiconductor nanostructure electrodes and filling the void spaces among the nanostructures with p-type semiconductor materials, unlike the known planar type inorganic thin film solar cells including n-type semiconductors and p-type semiconductors.

### CROSS-REFERENCE TO RELATED APPLICATIONS

This application claims priority under 35 U.S.C. §119 to Korean Patent Application No. 10-2011-0086514, filed on Aug. 29, 2011, in the Korean Intellectual Property Office, the disclosure of which is incorporated herein by reference in its entirety.

### TECHNICAL FIELD

The following disclosure relates to a bulk heterojunction inorganic thin film solar cell and a method for fabricating the same. More particularly, the following disclosure relates to a solar cell including an inorganic thin film having a bulk heterojunction formed by using vertically grown n-type semiconductor nanostructure electrodes and filling the void spaces among the nanostructures with p-type semiconductor materials, unlike the known planar type inorganic thin film solar cells including n-type semiconductors and p-type semiconductors. The following disclosure also relates to a method for fabricating the solar cell.

### BACKGROUND

It is said that a solar cell generating electricity directly from the sunlight is one of the most spotlighted future energy generation systems because it generates clean energy safely. To fabricate such solar cells, various kinds of inorganic and organic semiconductors have been used. However, solar cells that have succeeded in commercialization to date merely include silicon solar cells using silicon (Si) as a main material and copper indium gallium selenide (CIGS)-based thin film solar cells.

Although silicon solar cells have an advantage of high light conversion efficiency, they require high cost of manufacture. Thus, a lot of attention is given to manufacture of thin film solar cells using compound semiconductors amenable to thin film application with a smaller thickness.

To realize a high-efficiency solar cell, it is important to maximize light absorption. Further, it is very important for the charges (electrons and holes) generated by light absorption to be transferred toward electrodes without recombination, thereby generating actual electricity. To accomplish this, it is essentially required to minimize the charge transfer distance. However, the method including simply reducing the thickness of a thin film has a limitation in that it may reduce light absorption efficiency.

Meanwhile, inorganic thin film solar cells, also known as CIS solar cells based on compound semiconductors of Group I-III-VI elements (e.g.: CuInSe₂, CuInS₂ or CuInGaSe₂) have higher efficiency and stability as compared to organic solar cells. However, such inorganic thin film solar cells have been manufactured by a vacuum deposition process, and thus show a disadvantage of high cost of manufacture. To overcome the above-mentioned disadvantages of vacuum deposition-based CIS solar cells, active studies have been conducted to develop solution process-based CIGS thin film solar cells using ink or paste. However, such solution process-based CIGS thin film solar cells have a severe problem in that it is difficult to grow CIGS crystallites in such thin films. Selenization processes have been used to increase the size of CIS crystallites, but they have a problem related to the use of a toxic gas, such as H₂Se.

One of the problems caused by a small CIS crystallite size is formation of a lot of interfaces among the crystallites. Such interfaces accelerate recombination of electrons or holes, thereby making it difficult to separate charges and reducing the efficiency of a solar cell. Therefore, there is an imminent need for developing bulk heterojunction inorganic thin film solar cells capable of minimizing the charge transfer distance despite a small crystallite size in a thin film.

Although Korean Unexamined Patent Publication No. 10-2009-0104304 discloses a bulk heterojunction solar cell, it still requires improvement in terms of its manufacture and efficiency.

### SUMMARY

An embodiment of the present invention is directed to realizing a bulk heterojunction between a n-type semiconductor and a p-type semiconductor so that a charge transfer distance may be minimized for the purpose of efficient separation of charges generated in a thin film during the manufacture of an inorganic thin film solar cell. Particularly, some embodiments of the present invention are directed to providing a bulk heterojunction inorganic thin film solar cell using vertically grown nanostructure translucent electrodes and a p-type semiconductor coating process based on a cost-efficient solution process.

In one general aspect, there is provided a bulk heterojunction inorganic thin film solar cell, including:

a substrate;

an array of vertical nanostructure electrodes formed on the substrate;

a dense layer coated on the array of vertical nanostructure electrodes;

a p-type semiconductor thin film formed in the gaps of the dense layer-coated array of vertical nanostructure electrodes and thereon; and

a metal electrode formed on the p-type semiconductor thin film.

According to one embodiment, the vertical nanostructure electrodes may be transparent or translucent metal oxide electrodes. For example, the vertical nanostructure electrodes may be selected from the group consisting of nanorods and nanotubes formed of ZnO, TiO₂ or ITO materials.

According to another embodiment, the dense layer formed on the vertical nanostructure electrodes may be n-type oxide semiconductors, such as TiO₂ or ZnO.

According to still another embodiment, the solar cell may further include a n-type semiconductor buffer layer on the top of the dense layer, wherein the n-type semiconductor buffer layer may be a layer formed of a semiconductor selected from CdS, ZnS and In₂S₃.

According to still another embodiment, the p-type semiconductor material may include a material selected from Group I-III-1V elements.

According to yet another embodiment, the metal electrode may be formed by using Al, Au, Ag or carbon.

In another general aspect, there is provided a method for fabricating a bulk heterojunction inorganic thin film solar cell, including: forming an array of vertical nanostructure electrodes on a substrate; coating a dense layer on the array of vertical nanostructure electrodes; depositing ink or paste of a p-type semiconductor material in the gaps of the dense layer-coated vertical nanostructure electrodes so that the void spaces among the vertical nanostructures are filled with the ink or paste and a thin film is formed on the top of the vertical nanostructure electrodes, thereby forming a bulk heterojunction; and depositing a metal electrode on the bulk heterojunction thin film.

According to one embodiment, when forming an array of vertical nanostructure electrodes, the vertical nanostructures may be provided as nanorods or nanotubes of a transparent or translucent metal oxide, such as a ZnO, TiO₂ or ITO material through an electrochemical deposition, hydrothermal synthesis, chemical vapor deposition (CVD), anodizing or sputtering process. Particularly, the vertical nanostructures may have a height of 0.3-3 μm.

According to another embodiment, when coating a dense layer on the array of vertical nanostructure electrodes, the dense layer may be coated via an atomic layer deposition (ALD), CVD, dip coating or sol-gel process using a n-type oxide semiconductor, such as TiO₂ or ZnO. Particularly, the dense layer may have a thickness of 100 nm or less.

According to still another embodiment, the solar cell may further include a n-type semiconductor buffer layer on the top of the dense layer, and the n-type semiconductor buffer layer may be coated via a chemical bath deposition (CBD) process, etc., using a semiconductor selected from CdS, ZnS and In₂S₃. Particularly, the buffer layer may have a thickness of 10-200 nm.

According to still another embodiment, the p-type semiconductor material may include a material selected from Group elements, and the gaps of the array of vertical nanostructure electrodes and the top thereof may be filled with the p-type semiconductor material through a solution-based coating process selected from spin coating, spray coating and dip coating processes, using nanoparticle ink or a precursor solution thereof.

According to still another embodiment, the method may further include heat treating the p-type semiconductor material at a temperature of 400° C. or lower in air or under inert gas atmosphere in order to remove the remaining organic materials after coating the p-type semiconductor material.

According to yet another embodiment, the metal electrode may be formed via a vacuum deposition or solution deposition process using Al, Au, Ag or carbon.

Other features and aspects will be apparent from the following detailed description and the claims.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a schematic view showing the bulk heterojunction inorganic thin film solar cell to be realized according to one embodiment.

FIG. 2 is a block diagram showing the method for manufacturing a bulk heterojunction inorganic thin film solar cell using vertical nanostructures according to one embodiment.

FIG. 3 is a scanning electron microscope (SEM) image of ZnO and ITO nanostructures as examples of the vertical nanostructures formed according to one embodiment.

FIG. 4 is a SEM image of the vertical nanostructures coated with a TiO₂ dense layer and a CdS buffer thin film.

FIG. 5 is a transmission electron microscope (TEM) image of CuInS₂ nanoparticle ink used for depositing a p-type semiconductor according to one embodiment.

FIG. 6 is a SEM image of the bulk heterojunction inorganic thin film formed between ITO rods and CuInS₂ p-type semiconductor material according to one embodiment.

FIG. 7 is a graph showing the I-V characteristics of the solar cell obtained by using the bulk heterojunction inorganic thin film according to one embodiment.

### DETAILED DESCRIPTION OF EMBODIMENTS

The advantages, features and aspects of the present invention will become apparent from the following description of the embodiments with reference to the accompanying drawings, which is set forth hereinafter. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

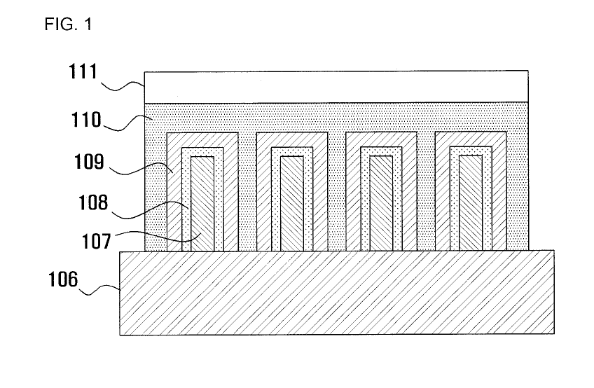

Referring to FIG. 1, in one aspect, a bulk heterojunction inorganic thin film solar cell, includes: a substrate 106; an array of vertical nanostructure electrodes 107 formed on the substrate; a dense layer 108 coated on the array of vertical nanostructure electrodes; a p-type semiconductor thin film 110 formed in the gaps of the dense layer-coated array of vertical nanostructure electrodes and thereon; and a metal electrode 111 formed on the p-type semiconductor thin film.

According to an embodiment, the bulk heterojunction inorganic thin film solar cell may further include a n-type semiconductor buffer layer 109 on the dense layer.

In another aspect, a method for fabricating a bulk heterojunction inorganic thin film solar cell, includes: forming an array of vertical nanostructure electrodes on a substrate; coating a dense layer on the array of vertical nanostructure electrodes; depositing ink or paste of a p-type semiconductor material in the gaps of the dense layer-coated vertical nanostructure electrodes so that the void spaces among the vertical nanostructures are filled with the ink or paste and a thin film is formed on the top of the vertical nanostructure electrodes, thereby forming a bulk heterojunction; and depositing a metal electrode on the bulk heterojunction thin film.

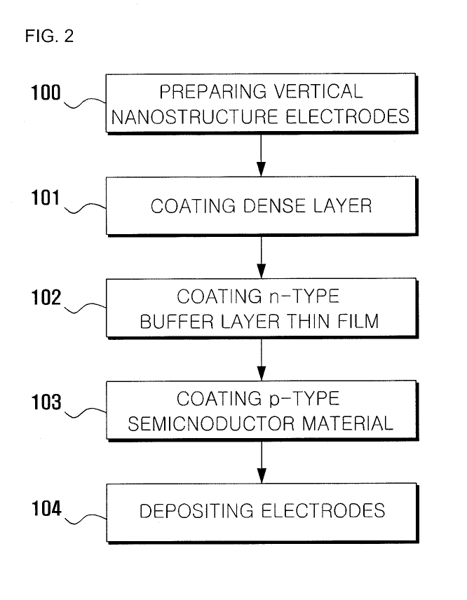

FIG. 2 is a block diagram showing the method for manufacturing a bulk heterojunction inorganic thin film solar cell according to one embodiment.

According to an embodiment, when forming an array of vertical nanostructure electrodes, the vertical nanostructure electrodes have the properties of a n-type semiconductor like ZnO, TiO₂ or ITO. When such vertical nanostructure electrodes are thin, they are transparent or translucent so that light may be transmitted therethrough. They are obtained by using conductive materials on a glass substrate. In general, such vertical nanostructure electrodes may be realized by electrochemical deposition, hydrothermal synthesis, CVD, anodizing or sputtering processes. In addition, it is possible to control the length of a nanostructure by modifying temperature, time, etc.

Next, a dense layer and a n-type semiconductor buffer layer are coated on the vertical nanostructures obtained as mentioned above. The dense layer is required to prevent any possible current leakage, and may be obtained by using a n-type oxide semiconductor, such as TiO₂ or ZnO, having a large energy band gap capable of light transmission. Although the dense layer may be deposited through a sol-gel process using a Zn or Ti precursor, an ALD process may be used in order to obtain uniform coating. Considering the light transmission and conductivity, the dense layer may have a thickness of 100 nm or less.

In addition, the n-type semiconductor buffer layer is required to facilitate the junction between a n-type semiconductor layer and a p-type semiconductor layer and to prevent counter-flow of electrons. In general, the n-type semiconductor buffer layer is provided by using compound semiconductors, such as CdS, ZnS or In₂S₃. Any deposition processes may be used as long as they allow uniform coating on the surface of an electrode. Particularly, a CBD process with high cost-efficiency may be used. The buffer layer may have a thickness of approximately 10-200 nm.

Then, the void spaces among the vertical nanostructure electrodes obtained as described above are filled with a p-type semiconductor material, thereby forming a bulk heterojunction inorganic thin film between a n-type semiconductor and a p-type semiconductor. The p-type semiconductor material may include a compound semiconductor formed of Group elements. More particularly, ink or paste of nanoparticles or precursor solutions of a CIS-based compound formed of Cu, In or Ga, Se or S may be used. To realize such a bulk heterojunction thin film, it is important to fill completely the void spaces among the vertical nanostructures with the p-type semiconductor material.

According to an embodiment, since the p-type semiconductor is formed on the vertical nanostructures by using a solution process-based coating method in the above-mentioned operation, it is possible to carry out heat treatment in order to remove the solvent or other organic substances and to improve the crystallinity of the p-type semiconductor material filled in the void spaces among the vertical nanostructures. The heat treatment may be carried out at a temperature of 400° C. or lower in air or under inert atmosphere. It is possible to reduce the amount of organic residues through such heat treatment, and thus to improve the efficiency of a solar cell.

Finally, a metal electrode is deposited on the bulk heterojunction thin film obtained as described above to provide a solar cell device. The metal electrode may be obtained by using materials and deposition processes known to those skilled in the art. Particularly, the metal electrode may be obtained by using Al, Au, Ag or carbon through a vacuum deposition process or solution deposition process.

As described above, the bulk heterojunction thin film obtained as disclosed herein is clearly differentiated from stack type thin film solar cells according to the related art, and is a novel structure. Particularly, it is possible to improve the efficiency and cost-efficiency of an inorganic thin film solar cell through the use of vertical nanostructures and an economical solution-based coating process in forming the bulk heterojunction hybrid thin film.

### EXAMPLES

The examples and experiments will now be described. The following examples and experiments are for illustrative purposes only and not intended to limit the scope of this disclosure.

### Example 1

### Fabrication of ITO and ZnO Vertical Nanostructures

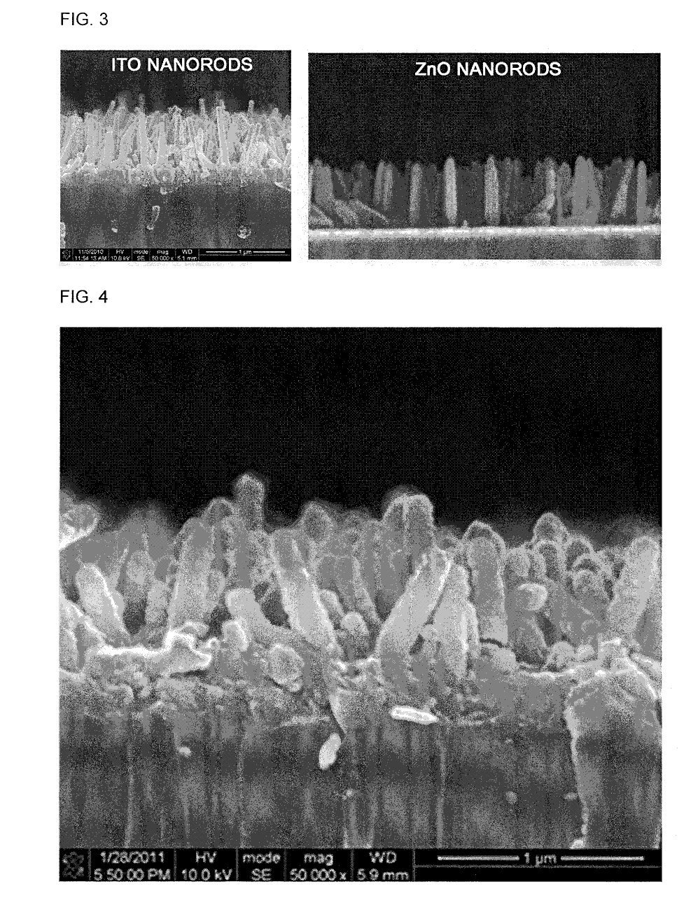

ITO vertical nanostructures are deposited on a glass substrate through a RF magnetron sputtering process. The glass substrate is ultrasonically washed with acetone, ethanol and distilled water and dried with nitrogen gas. Next, the washed substrate is heat treated at 120° C. for 1 hour. To perform deposition through sputtering, a preliminary vacuum of 2×10⁻⁶ Torr and a working vacuum of 7.8×10⁻³ Torr are required, and a RF power of 30 W is used. An ITO target is used as a catalyst for the fabrication of ITO vertical nanostructures. The sputter deposition is carried out at 500° C. for 1 hour. After the deposition, the sputtering chamber is cooled naturally to room temperature. The nanostructures formed in the above-described manner are shown in FIG. 3 as their SEM images. The ITO vertical nanostructures have an overall thickness of 100 nm and a length of 700 nm.

The ZnO vertical nanostructures are deposited on a glass substrate through a hydrothermal electrochemical process. As a working electrode, a chrome layer with a thickness of 50 nm and a platinum layer with a thickness of 50 nm are deposited on a single crystal silicon wafer 100 or polyethylene terephthalate (PET) by using a DC sputter. Then, a ZnO thin film with a thickness of 35 nm is deposited on the Pt-coated silicon substrate at 150° C. through an ALD process. As a counter electrode, a platinum layer (99.99%) is used. In addition, a Ag/AgCl electrode in saturated potassium chloride solution is used as a reference electrode. In other words, ZnO/Pt/Cr/Si or ZnO/Pt/Cr/PET is used as a working electrode. To perform the hydrothermal electrochemical process, a stainless steel autoclave with a Teflon liner is used. All of the electrodes are introduced into a solution of 0.012 g (0.1 mM) of Zn(NO₃)₃ in 420 mL of water. Then, 0.0059 g (0.015 mmol) of NaOH is further introduced thereto and the resultant solution is heated at a rate of 1.25° C./min to perform reaction for 1 hour. When the temperature reaches 90° C., a potential of 1.0 V is applied. After the completion of the reaction, the solution is cooled to room temperature.

### Example 2

### Preparation of Dense Layer and n-Type Semiconductor Buffer Layer Thin Film

A TiO₂ dense layer is prepared through an ALD process to obtain uniform coating. As a reaction gas, vaporized TiCl₄ and H₂O are used. As a substitution gas, argon gas is used. Atomic layer deposition is carried out for 8 cycles, wherein each cycle requires 1 second. The 8 cycles of atomic layer deposition includes vaporization of TiCl₄, recovery of gas, substitution with argon gas, recovery of gas, vaporization of H₂O, recovery of gas, substitution with argon gas, and recovery of gas. The flow rates of TiCl₄ and H₂O are 0.6 cm³/pulse and 0.5 cm³/pulse, respectively. Deposition is carried out under 40 Pa and gas recovery is carried out under 27 Pa. During the deposition and gas recovery, the temperature is set to 400° C. Each cycle is repeated 1000 times. As a result, a thin film with a thickness of 50 nm is obtained.

Then, a CdS n-type semiconductor thin film is obtained by using a CBD process with high cost-efficiency. To 200 mL of water, 0.0513 g (4 mM) of CdSO₄.5H₂O, 0.3806 g (0.05M) of H₂NCSNH₂, and 7.79 g (4M) of NH₄OH are dissolved. Then, the ITO vertical nanostructures are introduced into the beaker containing the solution. After carrying out reaction at 60° C. for 10 minutes, a thin film with a thickness of 50 nm is obtained. The SEM image of the resultant thin film is shown in FIG. 4. The ITO vertical nanostructures have an overall thickness of 150 nm and a length of about 1 μm.

### Example 3

### Preparation of Bulk Heterojunction Thin Film Through p-Type Semiconductor Deposition

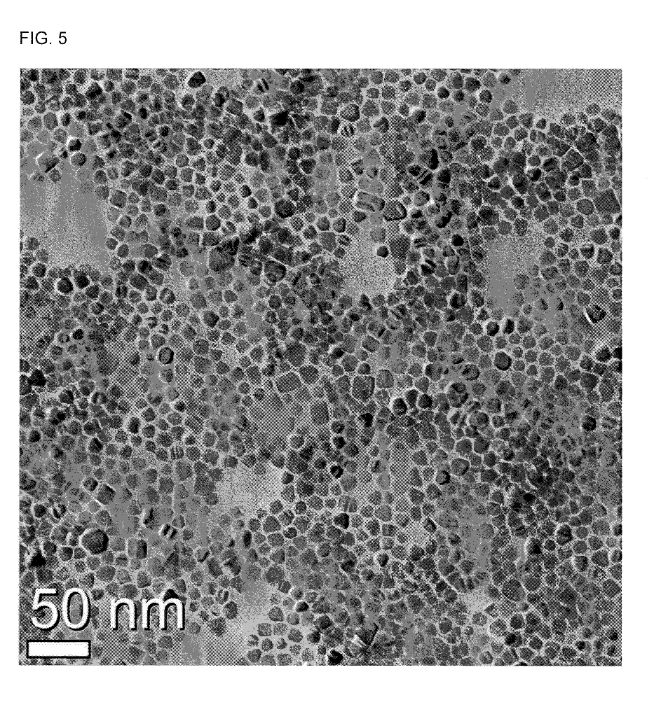

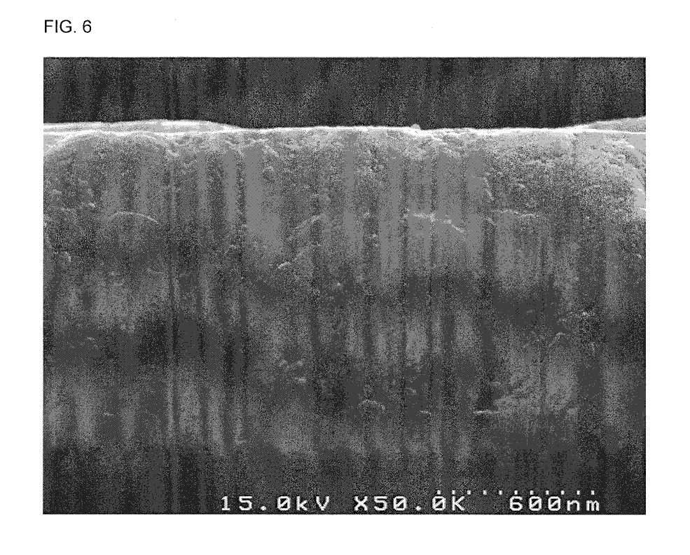

First, ink of CIS nanoparticles is obtained as follows. In 50 mL of oleyl amine, 0.495 g (5 mmol) of CuCl and 1.106 g (5 mmol) of InCl₃ are agitated. The resultant solution is subjected to vacuum for 30 minutes while heating it to 110° C. to remove impurities. Then, the solution is heated to 180° C. and 10 mL of oleyl amine and 0.32 g (10 mmol) of S are mixed vigorously. The resultant product is heated to 240° C. and allowed to react for 10 minutes, and then cooled to room temperature. After the product is washed with ethanol and toluene, it is redispersed in toluene to obtain CIS nanoparticle ink. The CIS nanoparticle ink includes particles with a size of about 10-15 nm and the morphology of the particles is shown in FIG. 5.

The ink is coated on the ITO vertical nanostructures via a wet method and heat treated at 350° C. for 10 minutes under argon atmosphere to obtain a CIS bulk heterojunction thin film. As can be seen from the SEM image of the CIS bulk heterojunction thin film, the ITO vertical nanostructures are filled completely with the CIS nanoparticles. The SEM analysis is carried out by using NanoSEM 200 available from NOVA, Co. (Japan).

### Example 4

### Fabrication of Bulk Heterojunction Inorganic Thin Film

The bulk heterojunction inorganic thin film obtained from Example 3 is used to fabricate a solar cell device by evaporating the Au electrode on the bulk heterojunction thin film.

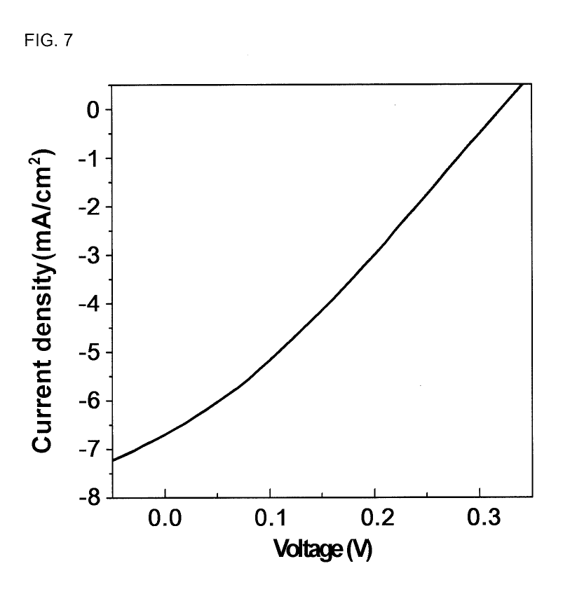

In addition, the operation of the device is analyzed in terms of I-V characteristics and the results are shown in FIG. 7. The I-V analysis is carried out by using CompactStat available from Ivium Technologies, Co. (Netherland). Further, for the AM 1.5 spectrum, Sun2000 solar simulator available from ABET Technologies, Co. (USA) is used.

The bulk heterojunction inorganic thin film disclosed herein realizes a bulk heterojunction between a p-type semiconductor material and a n-type semiconductor material, thereby minimizing a charge transfer distance. As a result, the bulk heterojunction inorganic thin film facilitates charge separation, and thus improves the efficiency of an inorganic thin film solar cell. In addition, the p-type semiconductor layer is deposited via a cost-efficient solution process during the manufacture of the bulk heterojunction inorganic thin film. Further, it is possible to control the composition of Group elements with ease, and thus to control energy band gaps as required. In this manner, it is possible to control the voltage and current of a solar cell.

While the present invention has been described with respect to the specific embodiments, it will be apparent to those skilled in the art that various changes and modifications may be made without departing from the spirit and scope of the invention as defined in the following claims.

What is claimed is:

1. A bulk heterojunction inorganic thin film solar cell, comprising:
a substrate;
an array of vertical nanostructure electrodes formed on the substrate;
a dense layer coated on the array of vertical nanostructure electrodes;
a p-type semiconductor thin film formed in the gaps of the dense layer-coated array of vertical nanostructure electrodes and thereon; and
a metal electrode formed on the p-type semiconductor thin film.

2. The bulk heterojunction inorganic thin film solar cell according to claim 1, wherein the vertical nanostructure electrodes are transparent or translucent metal oxide electrodes.

3. The bulk heterojunction inorganic thin film solar cell according to claim 1, wherein the vertical nanostructure electrodes are selected from nanorods and nanotubes formed of ZnO, TiO₂ or ITO materials.

4. The bulk heterojunction inorganic thin film solar cell according to claim 1, wherein the dense layer is a n-type oxide semiconductor.

5. The bulk heterojunction inorganic thin film solar cell according to claim 4, wherein the n-type oxide semiconductor forming the dense layer is TiO₂ or ZnO.

6. The bulk heterojunction inorganic thin film solar cell according to claim 1, which further comprises a n-type semiconductor buffer layer on the top of the dense layer.

7. The bulk heterojunction inorganic thin film solar cell according to claim 6, wherein the n-type semiconductor buffer layer includes a semiconductor selected from CdS, ZnS and In₂S₃.

8. The bulk heterojunction inorganic thin film solar cell according to claim 1, wherein the p-type semiconductor material includes a material selected from Group I-III-VI elements.

9. The bulk heterojunction inorganic thin film solar cell according to claim 1, wherein the metal electrode includes Al, Au, Ag or carbon.

10. A method for fabricating a bulk heterojunction inorganic thin film solar cell, comprising:
forming an array of vertical nanostructure electrodes on a substrate;
coating a dense layer on the array of vertical nanostructure electrodes;
depositing ink or paste of a p-type semiconductor material in the gaps of the dense layer-coated vertical nanostructure electrodes so that the void spaces among the vertical nanostructures are filled with the ink or paste and a thin film is formed on the top of the vertical nanostructure electrodes, thereby forming a bulk heterojunction; and
depositing a metal electrode on the bulk heterojunction thin film.

11. The method according to claim 10, wherein the vertical nanostructure electrodes are transparent or translucent metal oxide electrodes.

12. The method according to claim 10, wherein the vertical nanostructures are selected from nanorods or nanotubes of a ZnO, TiO₂ or ITO materials.

13. The method according to claim 10, wherein the vertical nanostructures are formed through an electrochemical deposition, hydrothermal synthesis, chemical vapor deposition (CVD), anodizing or sputtering process, in said forming an array of vertical nanostructure electrodes.

14. The method according to claim 10, wherein the vertical nanostructures have a height of 0.3-3 μm.

15. The method according to claim 10, wherein the dense layer is a n-type oxide semiconductor.

16. The method according to claim 15, wherein the n-type oxide semiconductor forming the dense layer is TiO₂ or ZnO.

17. The method according to claim 10, wherein the dense layer is coated via an atomic layer deposition (ALD), CVD, dip coating or sol-gel process, in said coating a dense layer on the array of vertical nanostructure electrodes.

18. The method according to claim 10, wherein the dense layer has a thickness of 100 nm or less.

19. The method according to claim 18, wherein the solar cell further includes a n-type semiconductor buffer layer on the top of the dense layer.

20. The method according to claim 19, wherein the n-type semiconductor buffer layer includes a semiconductor selected from CdS, ZnS and In₂S₃.

21. The method according to claim 19, wherein the n-type semiconductor buffer layer is coated via a chemical bath deposition (CBD) process.

22. The method according to claim 19, wherein the buffer layer has a thickness of 10-200 nm.

23. The method according to claim 10, wherein the p-type semiconductor material includes a material selected from Group elements.

24. The method according to claim 10, wherein the p-type semiconductor material is coated through a solution-based coating process selected from spin coating, spray coating and dip coating processes by using nanoparticle ink or a precursor solution thereof.

25. The method according to claim 10, which further comprises heat treating the p-type semiconductor material at a temperature of 400° C. or lower in air or under inert gas atmosphere in order to remove the remaining organic materials after coating the p-type semiconductor material.

26. The method according to claim 10, wherein the metal electrode is formed by using Al, Au, Ag or carbon.

27. The method according to claim 10, wherein the metal electrode is formed via a vacuum deposition or solution deposition process.
